(19) United States
(12) Patent Application Publication
(10) Pub. No.: US 2026/0172011 A1
(43) Pub. Date: Jun. 18, 2026

(54) Delay Line Unit Circuits and Methods

(71) Applicant: Arm Limited, Cambridge (GB)

(72) Inventors: Seshagiri Rao Bogi, Vizianagaram (IN); Gurupadayya Shidaganti, Dharwad (IN); El Mehdi Boujamaa, Valbonne (IN); Vijaya Kumar Vinukonda, Bangalore (IN)

(21) Appl. No.: 18/981,407

(22) Filed: Dec. 13, 2024

(51) Int. Cl. H03K 5/134; H03K 19/20; H03K 5/00

(52) U.S. Cl. CPC H03K 5/134; H03K 19/20; H03K 2005/00078; H03K 2005/00195

(57) ABSTRACT

A circuit includes: one or more delay line units, where each of the delay line units has a first portion and one or more second portions. The first portion includes a NAND gate and each of the one or more second portions includes a PMOS device and first, second, and third NMOS devices. Also, each of the one or more delay line units is configured for an AND gate logic operation. In addition, a method includes: receiving first and second input signals at a first portion of a delay line unit; and activating a first NMOS device to provide conduction to an outputof the delay line unit.At a second portion of the delay line unit, the first NMOS device is coupled between a reset input and the output, and the first NMOS device is activated upon receiving the first input signal.

### I.Field

The present disclosure is generally related to systems, methods, and devices for delay line unit circuitry.

### II.Description of Related Art

Droop detectors and delay monitors are gate delay-based voltage droop sensors that ensure the reliable and accurate operation of digital systems. Droop detectors primarily monitor voltage stability, identifying fluctuations in supply voltage (i.e., droops), while delay monitors focus on timing and synchronization within the system. These devices are widely used in high-speed communication, signal processing, and precision control systems to maintain system performance and stability.

In digital sensor design, resolution refers to the sensor's ability to detect and differentiate between fine levels of detail in the captured data. It encompasses both the granularity of the output signals and the precision of the sensor's measurements. Temporal resolution reflects the sensor's capability to track and respond to rapid changes in circuit behavior, enabling effective monitoring and optimization of dynamic systems. High-resolution sensors are especially important in, for example, artificial intelligence (AI) hardware, where precise voltage and timing control are desired for handling high-speed computations, and in automation systems, where detecting subtle changes ensures accurate decision-making and system reliability. Improved sensor resolution enhances the ability to optimize designs, debug circuits, and maintain performance, all of which are critical for various advancing technologies. Consequently, there remains a strong need for innovations that enhance sensor resolution to meet growing demands.

### III.Brief Description of The Drawings

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a diagram of an example circuit in accordance with various implementations described herein.

FIG. 2 is an example timing diagram in accordance with various implementations described herein.

FIG. 3 is a diagram of an example circuit in accordance with various implementations described herein.

FIG. 4 is a representative graph in accordance with various implementations described herein.

FIG. 5 is an operational method in accordance with various implementations described herein.

FIG. 6 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. Detailed Description

Implementations of the present disclosure are described below with reference to the drawings. In the description, common features are designated by common reference numbers throughout the drawings.

In one implementation, the present disclosure describes a circuit including one or more delay line units, where each of the delay line units has a first portion and one or more second portions. The first portion includes a NAND gate, and each of the one or more second portions includes a PMOS device and first, second, and third NMOS devices. Also, each of the one or more delay line units is configured for an AND gate logic operation.

In another implementation, the present disclosure describes a method that includes receiving first and second input signals at a first portion of a delay line unit, and activating a first NMOS device to provide conduction to an outputof the delay line unit. Also,at a second portion of the delay line unit, the first NMOS device is coupled between a reset input and the output. Moreover, the first NMOS device is activated upon receiving the first input signal.

In another implementation, the present disclosure describes a non-transitory computer-readable medium storing computer-readable code for fabrication of a circuit including: one or more delay line units, where each of the delay line units has a first portion and one or more second portions. The first portion includes a NAND gate, and each of the one or more second portions includes a PMOS device and first, second, and third NMOS devices. Also, each of the one or more delay line units is configured for an AND gate logic operation.

Inventive aspects are directed to a novel AND gate (e.g., delay line unit) circuit that includes a first portion comprising a NAND gate and a second portion incorporating a unique configuration of a PMOS device and three NMOS devices. Advantageously, this innovative arrangement enables the delay line unit to achieve faster operation and more rapid output transitions, thereby significantly improving the resolution of the delay line in voltage droop detection and delay monitoring circuits.

Specifically, in certain aspects, the second portion (e.g., the second stage) of the delay line unit includes an NMOS device configured to be activated concurrently with the NAND gate of the first portion. When input signals (e.g., I and R, as described herein) are received concurrently at the NAND gate and the NMOS device in the second portion, the NMOS device provides a conductive path that facilitates the rapid transition of the Y-output of the delay line unit. This simultaneous activation reduces delay and improves the timing accuracy of the circuit, enhancing its ability to detect and respond to voltage droops or timing variations with higher precision.

This novel configuration not only accelerates the output transitions but also minimizes propagation delay within the delay line, ensuring that the circuit can detect smaller variations in supply voltage or timing. The combination of the NAND gate in a first portion and the PMOS and three NMOS devices in a second portion creates a synergistic effect that optimizes both speed and reliability, making the design particularly advantageous for high-speed and precision applications. By integrating this inventive circuit design, the delay line unit offers improved temporal resolution, making it highly effective for use in modern digital systems, such as, for example, high-speed processors, AI accelerators, and automated control systems, where timing precision and rapid response are critical. This advancement establishes the proposed circuitry as a significant step forward in the design of delay line-based voltage droop detectors and delay monitors.

Certain definitions have been provided herein for reference. A droop detector is a circuit or component designed to monitor and detect voltage droop, which refers to transient reductions in supply voltage, often caused by sudden increases in load. The primary function of a droop detector is to sense these voltage fluctuations and trigger a response, such as supplying additional power or activating protective mechanisms to stabilize the voltage. Droop detectors are integral to power management systems, ensuring that electronic devices or circuits maintain consistent and stable power, even during transient load changes.

A delay monitor is a circuit or component used to measure and monitor time delays introduced by various elements within a system. Its primary purpose is to ensure that signals or processes occur within expected timing parameters. Delay monitors are critical in applications requiring precise timing and synchronization, such as high-speed computational circuits. They verify that signals arrive at specific points in a system with the correct timing relationships. Additionally, in systems where delay adjustments are necessary, delay monitors provide feedback for compensation or correction, enhancing timing accuracy and system performance.

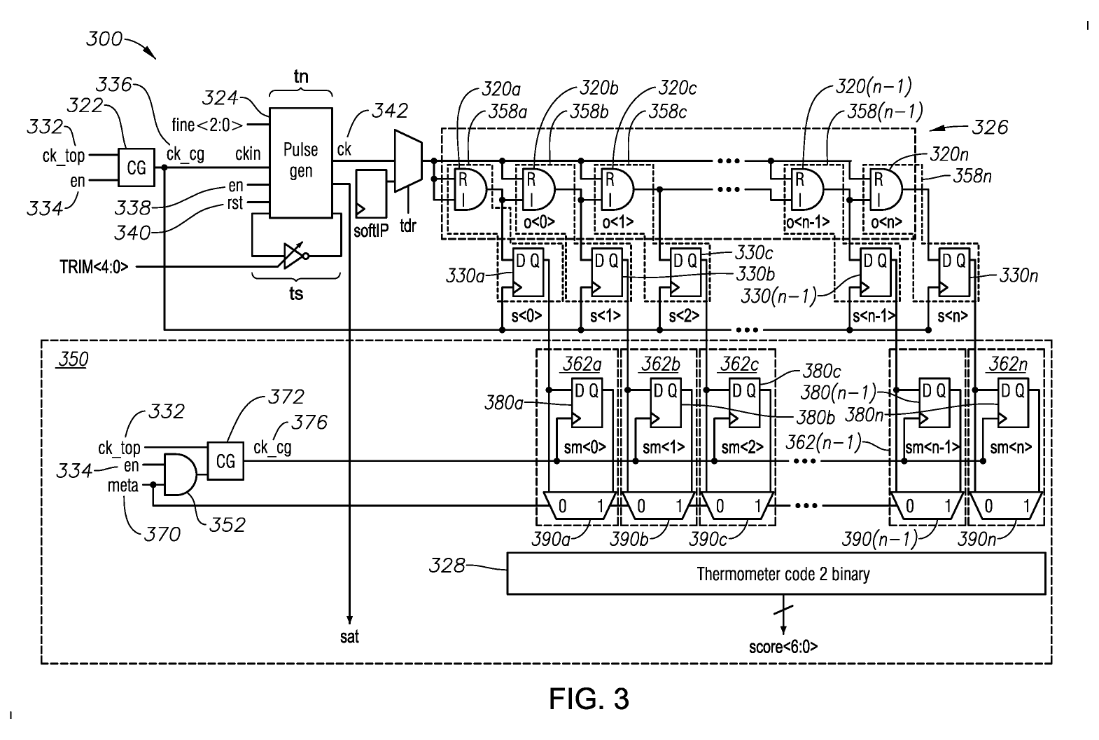

A thermometer-coded delay line is a delay line that employs a thermometer code to represent the delay introduced at each stage, commonly used in applications such as delay monitors. In this encoding scheme, each stage corresponds to a specific time delay increment, and the output is a binary sequence where a certain number of bits are set to "high" (1). The position and number of "high" bits indicate the cumulative delay at that stage. For example, in a 4-bit thermometer-coded delay line: 0001: Represents the shortest delay. 0011: Represents a slightly longer delay. 0111: Represents an even longer delay. 1111: Represents the longest delay. In digital circuitry, a thermometer code is a binary encoding scheme where each bit represents a sequential level or value, similar to markings on a thermometer. For instance, a thermometer code 2 binary uses two bits to represent values. As one example, the circuit 300 (as described herein with reference to FIG. 3) includes a 127 bit thermometer code to 7-bit (score) binary conversion. Hence, in this example, to provide a smaller notation, the thermometer code of 7-to-score-of bin<2:0> appears as: thermometer code 1111111 = score(7):111, thermometer code 0011111 = score(5):101 and so forth. Here, the highest bit (score[7]) represents the highest value, with subsequent bits (score[6], score[5], etc.) indicating decreasing levels. The output of a thermometer-coded delay line, derived from this encoding, represents a signal delayed in discrete steps. This delay line is instrumental in applications like signal alignment, time-domain adjustments, and synchronization in digital systems, where precise timing control is critical. The thermometer-coded structure ensures a clear representation of cumulative delay, enhancing the accuracy and usability of delay-based monitoring and control mechanisms.

A delay line refers to a sequential arrangement of logic gates, such as AND gates, designed to introduce controlled and incremental time delays to an input signal as it propagates through each stage. Each AND gate in the delay line contributes a specific delay, allowing precise monitoring and measurement of timing or voltage-related variations in the circuit. In such applications, the delay line serves as a critical component for detecting voltage droops or timing deviations by analyzing the timing relationships between input and output signals. For example, in a voltage droop detector, the delay line can help track supply voltage changes by correlating the delay increments with variations in circuit performance. Similarly, in a delay monitor, the delay line aids in capturing and adjusting timing shifts, ensuring synchronization and reliable operation of the digital system. The use of AND gates in the delay line enables fast, low-power operation while maintaining high resolution for detecting small changes in timing or voltage conditions.

VT-type refers to the voltage threshold classification of a transistor, which determines the minimum voltage required to switch the transistor from an "off" to an "on" state. A first VT-type can include low voltage thresholds such as Low Voltage Threshold (LVT), Ultra-Low Voltage Threshold (ULVT), or Extreme-Low Voltage Threshold (ELVT), characterized by faster switching speeds but higher leakage currents. A second VT-type can include higher voltage thresholds such as Standard Voltage Threshold (SVT) or High Voltage Threshold (HVT), which provide slower switching speeds but lower leakage currents. The VT-type defines the trade-off between performance and power efficiency in circuit design.

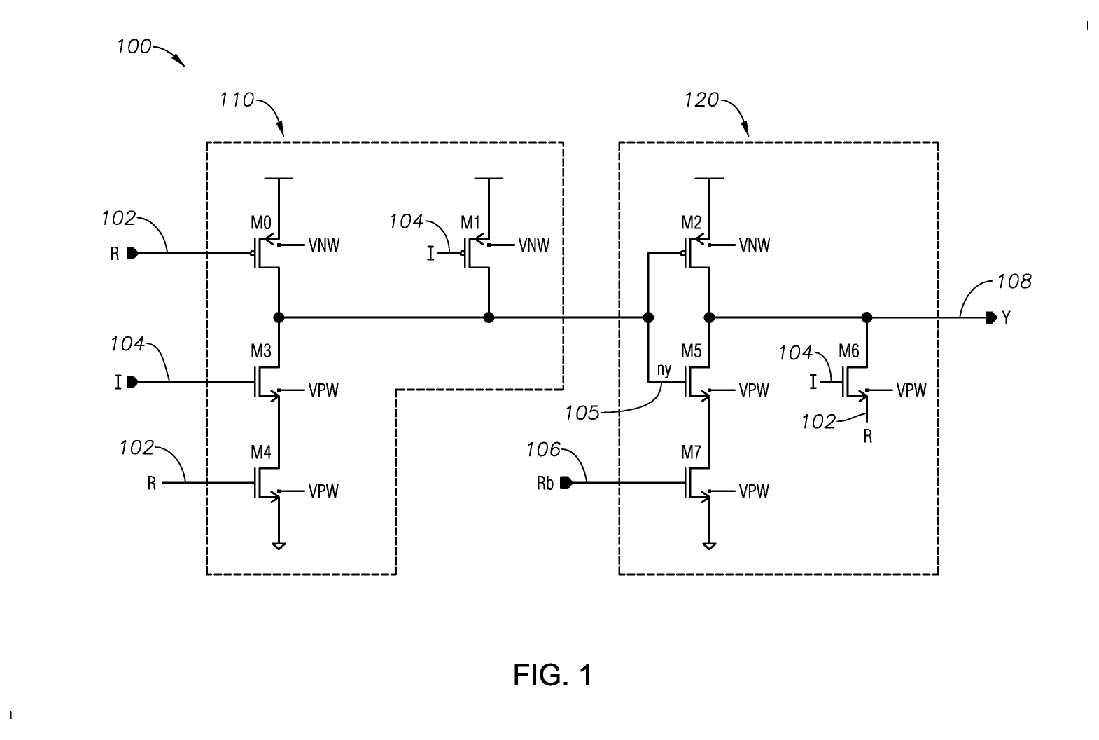

Referring to FIG. 1, an example delay line unit circuit 100 (e.g., AND gate) according to example implementations is shown. As may be appreciated, the example delay line unit circuit 100 (e.g., delay line unit) may be one of a plurality of delay line units of a delay line (e.g., as shown by delay line 326 in FIG. 3). As illustrated, the delay line unit 100 may include a first portion 110 and one or more second portions 120. The first portion 110 may be a NAND gate including PMOS transistors M0 and M1 (e.g., PMOS devices) and NMOS transistors M3 and M4 (e.g., NMOS devices), where the M1 and M3 transistors receive a first input signal (I) 104 (e.g., corresponding to an output signal of a preceding delay line unit), and where the M0 and M4 transistors receive a second input signal (R) 102 (e.g., a parallel input signal).

In various implementations, as shown in FIG. 1, each of the one or more second portions 120 may include a PMOS transistor M2 (e.g., a PMOS device) and first, second, and third NMOS transistors M6, M5, and M7 (e.g., first, second, and third NMOS devices). Also, the delay line unit 100 may be configured for an AND gate logic operation. Correspondingly, with reference to FIG. 3, each delay line unit of an example delay line may also be configured for an AND gate logic operation.

In certain cases, as illustrated, for a respective delay line unit 100, the first NMOS device M6 is coupled between an output of the respective delay line unit (Y) and a reset input (R). Also, for a respective delay line unit 100, a gate input of the PMOS device (M2) is coupled to a gate input of the second NMOS device (M5). In addition, for a respective delay line unit 100, the second and the third NMOS devices (M5 and M7) are coupled in series.

In some instances, for a respective delay line unit 100, the first and second input signals (I 104 and R 102) are provided to the NAND gate 110. Also, the same first input signal 104 (I) can be configured to activate (e.g., can provided to a gate of) the first NMOS device (M6).

In one example, for a respective delay line unit 100, in response to activation of the first NMOS device (M6), the first NMOS device (M6) is configured to provide (initial) conduction (e.g., by electrical charge) to an output (Y) 108 of the respective delay line unit 100. In addition, for such an example, in response to a deactivation of the second NMOS device (M5) (e.g., ny signal goes to “0”), the PMOS device (M2) can be configured to provide conduction (e.g., by electrical charge) of the output (Y) 108 of the respective delay line unit 100.

In one example, for a respective delay unit 100, first and second input signals (I 104 and R 102) are provided to the NAND gate 110. Also, an inverse of the second input signal (e.g., the inverse signal being Rb) is configured to activate (e.g., is provided to a gate of) the third NMOS device (M7); and in response to an activation of the third NMOS device (M7), the third NMOS device (M7) is configured to reset (each of the transistor devices of) the respective delay line unit 100.

In one example, for a respective delay line unit 100, first and second input signals (I) 104 and (R) 102 are provided to the NAND gate 110. Also, the first input signal (I) 104 would correspond to an output signal of a preceding (previous) delay line unit of the one or more delay line units, and the second input signal corresponds to a parallel input signal (R) 102. In addition, an inverse (Rb 106) of the same second input signal (R) 102 can be configured to concurrently reset the one or more delay line units (with reference to FIG. 3). In certain implementations, the circuit 100 may be included within a time-digital-conversion (TDC) circuit (e.g., voltage droop detector/ delay monitor system).

Moreover, while FIG. 1 illustrates an example circuit with one second portion 120, in alternative example implementations, additional second portions may be added. For example, a first additional second portion (e.g., 2PMOS 6NMOS implementation (not shown)) may have duplicate transistors for M2, M6, M5, and M7 coupled in parallel to the original second portion 120 between the first portion 110 and output Y 108. Similarly, additional second portions may be included in the circuit 100, and also coupled in parallel to the original second portion 120 between the first portion 110 and output Y 108. Advantageously, such implementations can further provide greater resolution.

In certain implementations, the first NMOS device (e.g., M6) can be designed to be a same or lower VT-type device in comparison to the second and third NMOS devices (e.g., M5 and M7). Advantageously, such a feature allows a faster rise of the output Y 108, and thus higher resolution. Furthermore the advantage can also be realized by a same or lower VT-type, however in such cases, the same VT-type device would be sized “larger” in size in comparison to the lower VT-type device. Also, as shown in FIG. 1, for body biasing, VNW (N-well voltage) can be applied to the N-well or body terminal of each of the PFET devices of the circuit 100. Likewise, also for body biasing, VPW (P-well voltage) can be applied to the P-well or body terminal of each of the NFET devices of the circuit 100.

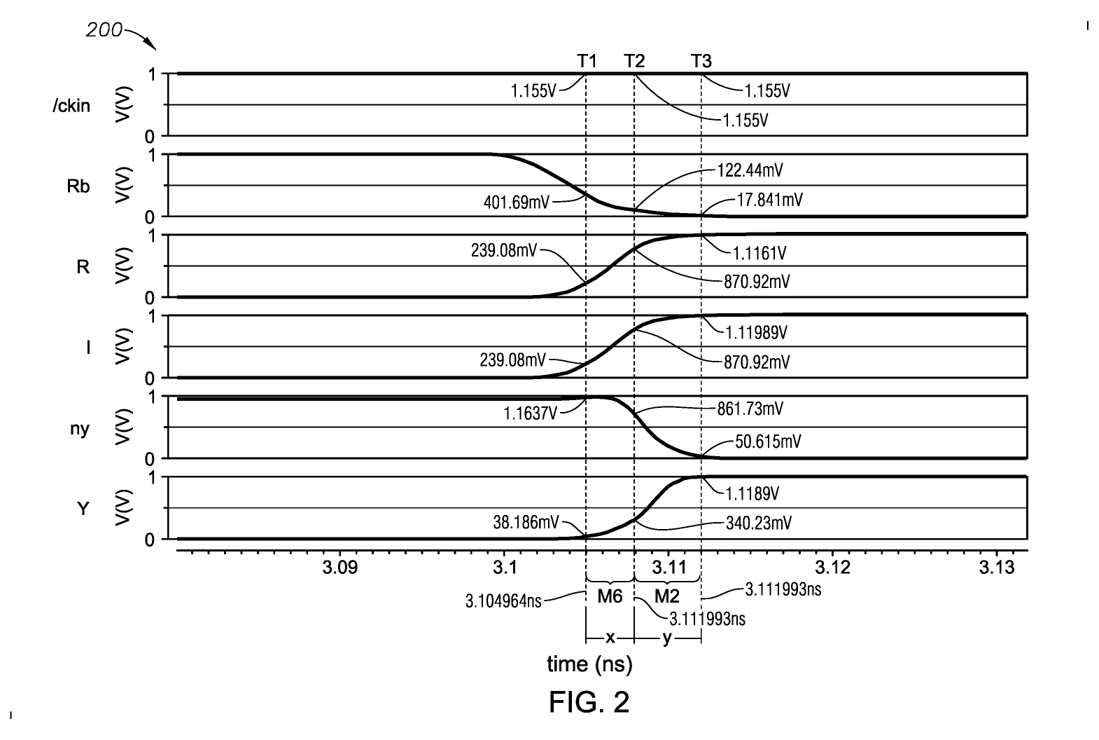

Referring to FIG. 2, an example timing diagram 200 discussed with reference to the circuit 100 (e.g., inventive AND gate) in FIG. 1 according to example implementations. In an example operation, as illustrated, input signals R and I are initially asserted at low states (e.g., digital “0”), while /ckin (e.g., a clock input signal) and Rb (e.g., reset signal) are initially asserted as high states (e.g., digital “1”). Based on these initial assertions, the ny signal (e.g., intermediate signal corresponding to an output of the NAND gate 110) is initially at a high state (e.g., a digital “1”), whereas the Y-output 108 is initially at a low state (e.g., digital “0”).

Subsequently, whenever an input signal arrives, for example, I signal 104 (e.g., output of a previous AND gate) is asserted as a “1” (and before the ny signal becomes “0”), the circuit 100 attempts to the couple R signal 102 (e.g., a parallel input) with the Y-output 108. Thus, when an input arrives, the circuit 100 can “pump” directly to the second portion (e.g., the second stage) using the R signal 102. By doing so, initially, at a first time interval (e.g., interval x; the duration between times T1 and T2), the M6 transistor is configured to provide conduction to (e.g., charge) the Y-output 108. Next, at a second time interval (e.g., interval y; the duration between times T2 and T3), as the ny signal transitions to “0”, the M2 device is configured to provide conduction to (e.g., charge) the Y-output 108. In doing so, the transition of the Y-output 108 would occur faster.

FIG. 2 also illustrates the operation of a reset signal (Rb). As an example, for a reset, the Y output 108 (and, for example, each of the Y outputs 108 of a delay line with reference to FIG. 3) is required to be at a digital “0”. As such, at such a reset time, the R and I signal inputs would each assert a digital “0”, and thus, the M6 device would become inefficient, and would not be able to bring the Y-output 108 to “0”. To account for such a scenario, an Rb signal 106 (e.g., reset signal; inverse to the R signal 102) can activate the M7 transistor to “pull” all the transistors (e.g., all the Y-outputs/Y-nodes of the delay line/ delay chain) to low (e.g. a digital “0”). Advantageously, upon traveling a signal through a delay line, for each delay line unit, a respective M6 device (as illustrated in FIG. 1) will aid in conduction of a respective Y-output. In addition, the M7 device (as illustrated in FIG. 1) will aid in a reset operation.

FIG. 3 is a diagram of an example circuit 300 (e.g., system 300), in accordance with certain implementations. As illustrated, the example system 300 (e.g., time-to-digital (TDC) architecture 300, digital voltage sensor circuit) corresponds to a voltage droop detector and delay monitor. In various implementations, the system is configured to predict (e.g., monitor) a voltage droop (on a critical path) of a separate processing unit (e.g., CPU/GPU/NPU 612).

The example circuit 300 includes a delay line 326 including one or more delay line units 320A, 320B, 320C, … 320(N-1), and 320N, each corresponding to the delay line unit 100 in FIG. 1. Advantageously, the delay line 326 is configured to provide faster delay line unit output transitions, and thus, can provide an improved delay line resolution. The example circuit 300 also includes flip-flops 330A, 330B, 330C, … 330(N-1), and 330N capture a respective transition to a digital high state (1) and in response to a rising edge of the clock input signal (ckin) (corresponding to ck_cg 336). Also, for example, each delay line unit (e.g., one of 320A, 320B, 320C, … 320(N-1), and 320N) and each corresponding flip-flop (e.g., one of 330A, 330B, 330C, … 330(N-1)) in combination corresponds to a respective delay capture unit (e.g., one of 358A, 358B, 358C, 358D, …, 358(N-1), and 358N). For instance, the delay code capture units 358A, 358B, 358C, 358D, …, 358(N-1), and 358N include one or more digital gates (e.g., one or more delay line units) that are more sensitive to voltage changes than the grouping of digital gates in a critical path of processing unit circuitry 712 of the one or more computer devices 610, 620, and 630.

Advantageously, one or more digital gates of the delay code capture units 358A, 358B, 358C, 358D, …, 358(N-1), and 358N (that are more sensitive to voltage change transition) can detect a voltage droop a “somewhat earlier” than an impact of the voltage droop on the critical path. Hence, allowing for anticipation of issues on the critical path, and a capacity to react to such issues (e.g., by reducing a clock frequency, and the like). In one example, the delay code capture units 358A, 358B, 358C, 358D, …, 358(N-1), and 358N include one or more digital gates with a same or lower voltage threshold (VT) in comparison type for increased sensitivity. In another example, one or more digital gates of the delay code capture units 358A, 358B, 358C, 358D, …, 358(N-1), and 358N include special gate sizing for increased sensitivity.

As illustrated in FIG. 3, the example digital voltage sensor circuit 360 includes a clock generator circuit 322 and a pulse generator circuit 324 that operably couple the delay line circuit 326. As shown, the clock generator circuit 322 includes two inputs: a primary clock signal (ck_top) 332 that provides a base frequency and acts as a reference for the clock generator circuit 322 and an enable signal (en) 334 that can control the operation of the clock generator circuit 322. In response to the enable signal (en) 334 being active (e.g., a digital logic high state (“1”)), the clock generator circuit 322 can be enabled and produce a clock signal (ck_cg) 336. Alternatively, in response to the enable signal (en) 334 being inactive (e.g., a digital logic low state (“0”)), the clock generator circuit 322 can be designed to stop producing the clock signal (ck_cg) 336. Further, the clock generator circuit 322 can create the clock signal (ck_cg) 336 with fine-grained control (fine<2:0>) over frequency or timing characteristics. Moreover, the clock signal (ck_cg) 336 can represent a 3-bit signal (e.g., fine2, fine1, and fine0) that provides fine-grained control over the generated clock's frequency or phase. For example, the 'fine<2:0>' output might indicate different configurations or settings related to the frequency, phase shift, or other characteristics of the clock signal (ck_cg) 336. Accordingly, the clock generator circuit 322 can control frequency adjustments in smaller increments than the primary clock signal (ck_top) 332.

The pulse generator 324 receives an enable signal (en) 338 as a control signal for activation. In response to the enable signal (en) 338 being active (e.g., often driven to a digital logic high state (1) or a digital logic low state (0), depending on a specified design), the enable signal (en) 338 can allow the pulse generator 324 to operate and generate pulses according to configured settings. Additionally, resetting or initializing the pulse generator 324 to a predefined state is a reset input (rst) 340. In response to the reset input (rst) 340 receiving a signal (such as a pulse, logic level change, or trigger), the reset input (rst) 340 resets the internal state of the pulse generator 324, often clearing ongoing operation or resetting configured parameters to default values. Also, the clock signal (ck_cg) 336 can be used to synchronize the generation of the clock signal (ck) 142, where the clock signal’s (ck) timing or frequency is determined by the frequency of the clock signal (ck_cg) 336.

In certain implementations, the example digital voltage sensor circuit 300 can be configured to identify a circuit signal path of the processing unit circuit 712. Functionally, the circuit signal path (not shown) can include a circuit where operation of a plurality of digital gates can include the plurality of transistors configured to process data between two flip-flops in approximately a clock period. In one operation, for a predetermined amount of time, the output clock signal (ck) 342 can be held at a digital logic low state (0) and outputs o<0>, o<1>, o<2>, o<n-1>, and o<n> of the delay line units (e.g., AND gates) 320A, 320B, 320C, 320D, …, 320(N-1), and 320N in the delay line circuit 326 are set to a digital logic low state (0). For instance, the setting to a digital logic low state (“0”) for the delay line units (e.g., AND gates) 320A, 320B, 320C, 320D, …, 320(N-1), and 320N takes one gate delay (the time taken for the clock signal (ck) 342 to propagate through a logic gate from its input to its output). Therefore, a digital logic low state (0) propagates through the delay line circuit 326 “quickly” (e.g., approximately one gate delay). Continuing with such an example, in response to the output clock signal (ck) 342 transitioning from a digital logic low state (0) to a digital logic high state (1), the delay line units (e.g., AND gates) 320A, 320B, 320C, 320D, …, 320(N-1), and 320N transition to the digital logic high state (1) value one after another. For example, after a first delay of a first AND gate 320A, output o<0> transitions to a digital logic high state (1). After a second delay of a second AND gate 320B, output o<1> transitions to a digital logic high state (1) and so on down the delay line circuit 326. In response to the clock signal (ck_cg) 336 transitioning from a digital logic low state (0) to a digital logic high state (1), there can be a propagation of the output clock signal (ck) 342 at a digital logic high state (1) into the delay line circuit 326. Further, in response to a next rising edge of the clock signal (ck_cg) 336, flip-flops 330A, 330B, 330C, … 330(N-1) and 330N capture a respective transition from digital logic low state (0) to a digital logic high state (1) and output their respective states to respective code selection unit 362. In other implementations (not shown), the output would directly be provided as thermometer coded output.

As illustrated in FIG. 3, a respective code selection unit of code selection units 362A, 362B, 362C, …, 362(N-1), and 362N can be coupled to each of the delay code capture units 358A, 358B, 358C, 358D, …, 358(N-1), and 358N. Each of the code selection units 362A, 362B, 362C, …, 362(N-1), and 362N can include a flip-flop, such as flip-flops 380A, 380B, 380C, …, 380(N-1), and 380N and a multiplexer, such as multiplexers 390A, 390B, 390C, …, 390(N-1), and 390N. In addition, the example voltage sensor circuit 300 can include a voltage droop selection circuit 350 that can include a second clock generation circuit 372; and an AND gate 352. Additionally, the voltage droop selection circuit 350 is configured to enable selection, by the code selection units 362A, 362B, 362C, …, 362(N-1), and 362N, of one or more respective code outputs s<0>, s<1>, s<2>, …, s<n-1>, s<n>, from the delay code capture units 358A, 358B, 358C, 358D, …, 358(N-1), and 358N.

Moreover, in FIG. 3, the AND gate 352 includes two inputs—one connected to a meta input 370 and the other input to the enable input 334. In response to both inputs of the AND gate 552 being active (for example, the meta input 370 and the enable input 334 are both a digital logic high state (1)), the AND gate 352 produces an output signal. The output signal of the AND gate 352 feeds into the clock generator 322 and can act as a gating mechanism that allows a clock signal (ck_cg) 376 to output only in response to both the meta input 370 and the enable input 334 are in specific states (e.g., a digital logic high state (1)). Further, the meta input 370 also serves as a selection signal for the multiplexers 390A, 390B, 390C, …, 390(N-1), and 390N. Additionally, the meta input 370 determines which of the two inputs (i.e., the s<n> of the delay code capture units 358A, 358B, 358C, 358D, …, 358(N-1), and 358N or sm<n> of the code selection units 362A, 362B, 362C, …, 362(N-1), and 362N of the multiplexers 390A, 390B, 390C, …, 390(N-1), and 390N is selected for a thermometer coded output 328 based on the state of the meta input 370. Hence, the meta input 370 effectively controls the switching or selection between different input sources for the multiplexers 390A, 390B, 390C, …, 390(N-1), and 390N.

One advantage of the example digital voltage sensor circuit 300 is its ability to improve the reliability of the output code. Specifically, by selecting the output (e.g., sm<n>) of the code selection units 362A, 362B, 362C, …, 362(N-1), and 362N, the circuit introduces a delay of one full clock cycle before producing the output. This delay mitigates potential issues related to metastability, a condition where a flip-flop or other circuit element temporarily resides in an undefined state due to timing conflicts during transitions between logic levels. The delay mechanism allows sufficient time for any metastability in the delay line 326 to resolve, stabilizing signals and enabling the system to settle into a stable state. This significantly enhances the reliability of the thermometer-coded output 328. By providing additional time for metastability resolution, the example digital voltage sensor circuit 300 minimizes or eliminates output errors caused by metastability issues, thereby improving overall circuit reliability. This advantage extends to the voltage droop selection circuit 550, which benefits from the enhanced stability and further increases data reliability by improving metrics such as mean time between failures (MTBF), a standard measure of the expected time between failures in a system or device.

In an example operation, when the meta input 370 is at a digital logic low state (0), the multiplexers 390A, 390B, 390C, …, 390(N-1), and 390N route the outputs of the delay code capture units 358A, 358B, 358C, 358D, …, 358(N-1), and 358N, while the clock generator 372 is disabled. This configuration consumes no power in the code selection units 362A, 362B, 362C, …, 362(N-1), and 362N. Additionally, selecting the outputs of the delay code capture units is faster, as there is no waiting period for a full clock cycle. Conversely, in another operation, when the meta input 370 is at a digital logic high state (1), the multiplexers 390A, 390B, 390C, …, 390(N-1), and 390N route the outputs of the code selection units 362A, 362B, 362C, …, 362(N-1), and 362N, and the clock generator 372 is enabled to provide the clock signal (ck_cg) 376. While this configuration consumes additional power in the code selection units, it ensures that the output is less prone to errors, albeit with a slower response due to the required full clock cycle delay.

In digital circuitry, a thermometer code is a binary encoding scheme where each bit represents a specific level in a sequence. Similar to the markings on a thermometer, where each mark indicates a specific temperature, each bit in a thermometer code corresponds to a particular value. For example, the thermometer code 2 binary 328 uses two bits to represent values. As one example, the circuit 300 includes a 127 bit thermometer code to 7-bit (score) binary conversion. Hence, in this example, to provide a smaller notation, the thermometer code of 7-to-score-of bin<2:0> appears as: thermometer code 1111111 = score(7):111, thermometer code 0011111 = score(5):101 and so forth. Here, the highest bit (score[7]) represents the highest value, with subsequent bits (score[6], score[5], etc.) indicating decreasing levels. The output of a thermometer-coded delay line, derived from this encoding, represents a signal delayed in discrete steps. This delay line is instrumental in applications like signal alignment, time-domain adjustments, and synchronization in digital systems, where precise timing control is critical. The thermometer-coded structure ensures a clear representation of cumulative delay, enhancing the accuracy and usability of delay-based monitoring and control mechanisms.

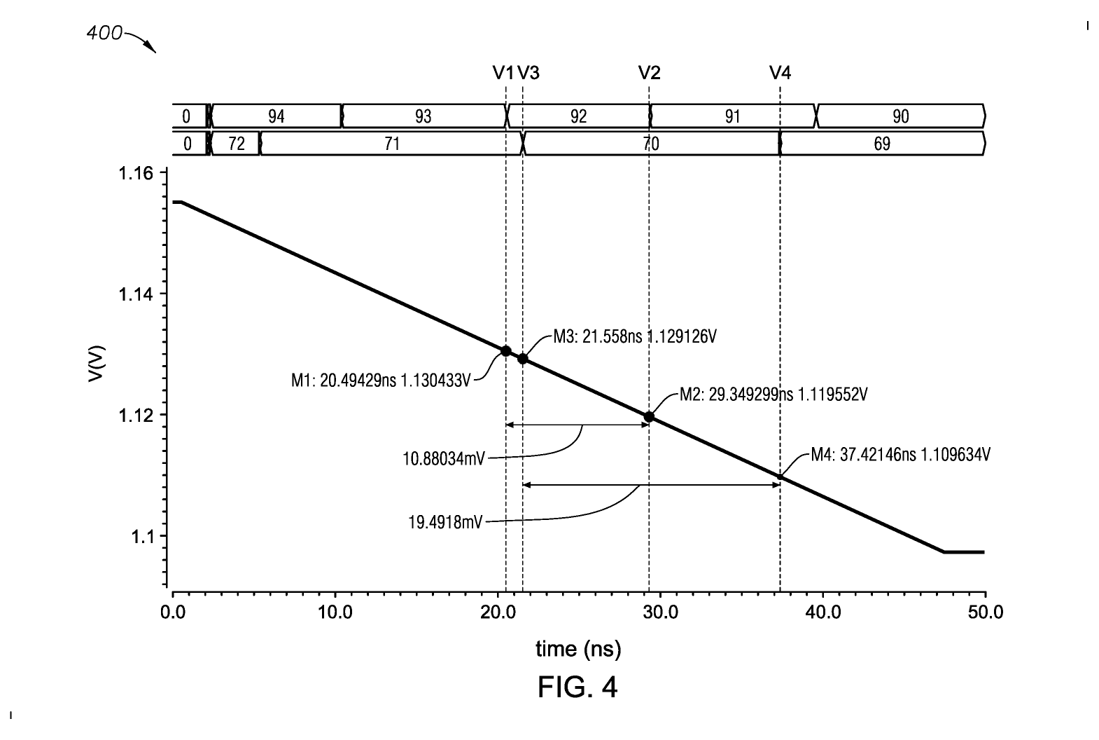

Referring to FIG. 4, an example graph 400 depicting resolution is shown. The graph 400 illustrates the improvement in resolution achieved by an example proposed inventive designs compared to the current state of the art. In the known art, a voltage change of approximately 19.5 millivolts (mV) in the supply voltage (Vdd) is required to trigger a change in the output code. However, with the proposed design, the required voltage change is significantly reduced to approximately 10.8 mV, representing nearly a 50% improvement in resolution. This improvement is particularly critical in worst-case scenarios (e.g., corner cases), where high-resolution voltage monitoring is essential. In typical scenarios, such as at higher operating voltages, the resolution requirement is less stringent, but reducing the required voltage change enhances the system's sensitivity to small variations. One key advantage of this proposed design is its ability to detect minor voltage fluctuations, making it highly effective for applications such as voltage droop detection or delay monitoring. With this improvement, the system can more easily identify small changes in voltage, enhancing overall performance and reliability.

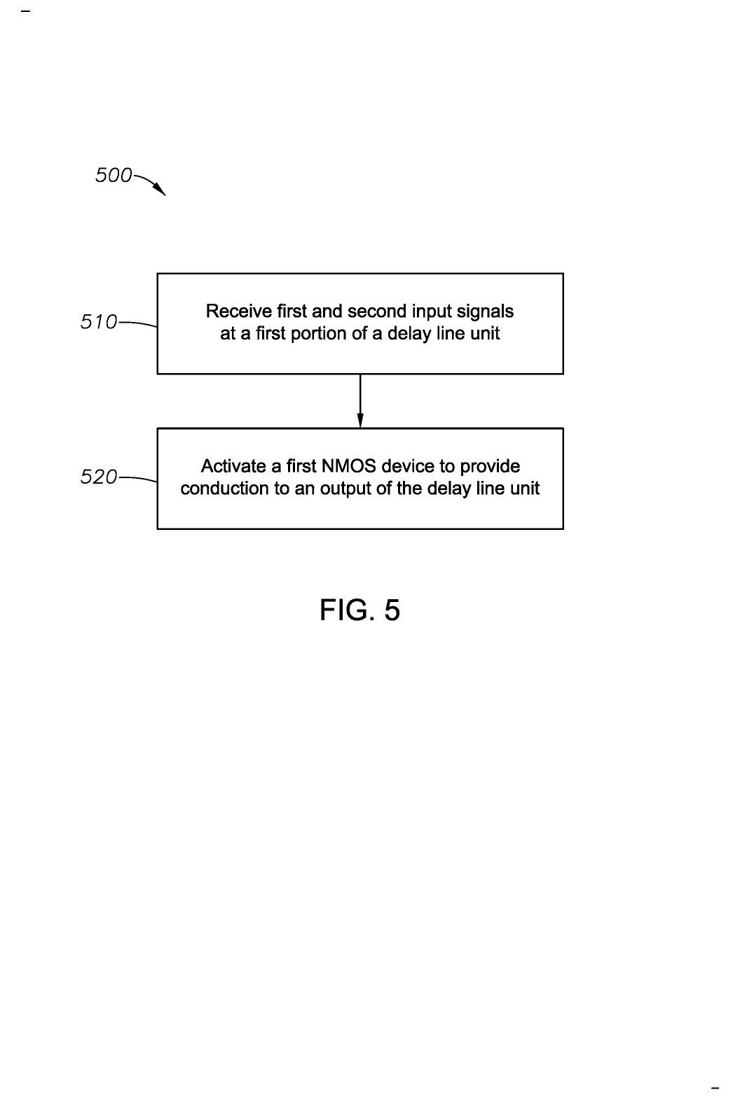

Referring to FIG. 5, a flowchart of an example operational method 500 (i.e., procedure) is shown. Advantageously, in various implementations, the method 500 describes the capability for faster delay line unit (e.g., AND gate) operation and output transition. The method 500 may be implemented with reference to implementation as shown with reference to FIGS. 1-4.

At block 510, the example method 500 includes: receiving first and second input signals at a first portion of a delay line unit. For instance, as described with reference to FIGS. 1-4, first and second input signals 104 and 102 (I and R) can be received at a first portion 110 (e.g., NAND gate) of a delay line unit (100, 320A, 320B, 320C, 320(N-1).

At block 520, the example method 500 includes: activating a first NMOS device to provide conduction to an output of the delay line unit. For instance, as described with reference to FIGS. 1-4, a first NMOS device (M6) of a second portion 120 may be activated to provide conduction to an output 108 (Y) (e.g., M6 conduction) (e.g., at an initial phase/stage of the transition) of the delay line unit 100. In certain implementations, at a second portion of the delay line unit, the first NMOS device (M6) may be coupled between a reset input and the (same) output (Y); and the first NMOS device (M6) may be activated upon receiving the (same) first input signal (I).

In some cases, the example method 500 includes: the first portion corresponding to a NAND gate, and in response to a transition of an output of the NAND gate (e.g., ny signal discharging “0”, and input to PMOS going high), providing conduction to (e.g., charging) the output (Y) (e.g., M2 conduction) through a PMOS device (M2) of the second portion. In such cases, a gate of the PMOS device (M2) is coupled to a gate of a second NMOS device (M5) of the second portion, an the second NMOS device (M5) is coupled to a third NMOS device (M7) in series. Additionally, the method 500 includes: activating the third NMOS device (M7) to reset the delay line unit, where: the third NMOS (M7) device is activated upon receiving an inverse (Rb) of the second input signal (R). In certain examples, the first input signal (I) corresponds to an output signal of a preceding (previous) delay line unit of two or more delay line units; the second input signal (R) corresponds to a parallel input signal; and an inverse (Rb) of the second input signal (R) is configured to concurrently reset the two or more delay line units of a delay line.

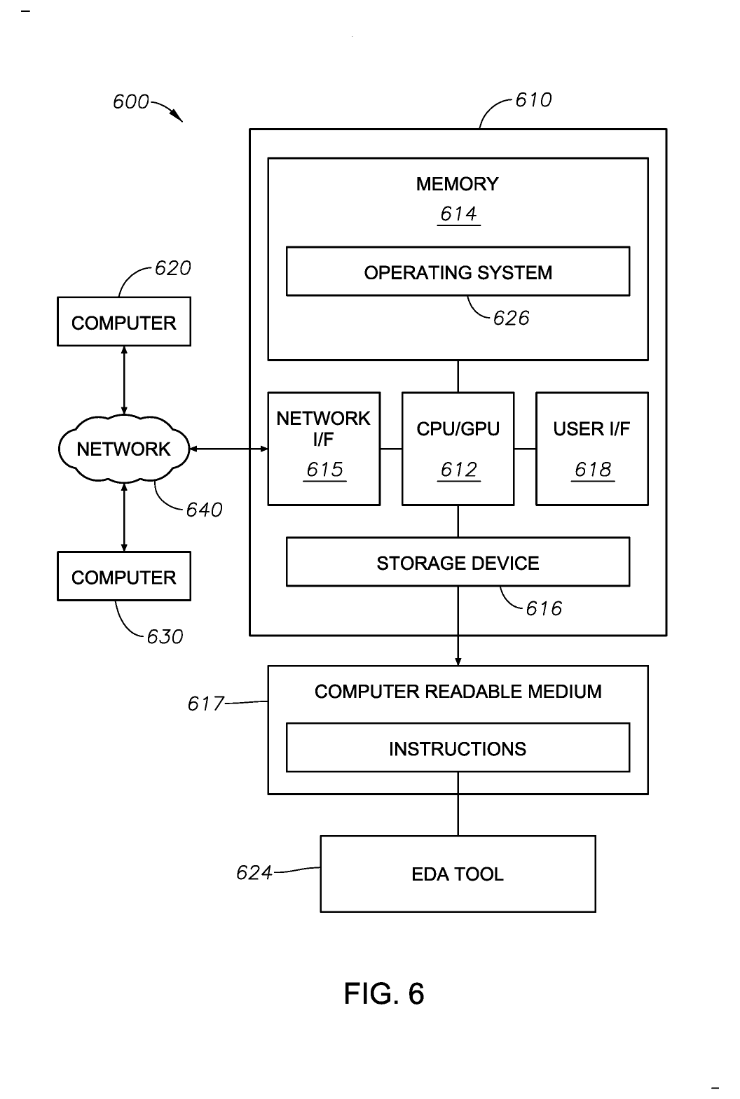

FIG. 6 illustrates example hardware components in the computer system 600 that may be used to facilitate and generate the inventive circuit design/memory architecture output. In certain implementations, the example computer system 600 (e.g., networked computer system and/or server) may include EDA tool 624 and execute software based on the procedure as described with reference to the methods as described herein.

FIG. 6 illustrates example hardware components in the computer system 600 that may be used to optimize droop detection of digital gates in a digital voltage sensor/detector circuit. In certain implementations, the example computer system 600 (e.g., networked computer system and/or server) may include circuit design tool 624 (e.g., EDA tool) and execute software based on the procedure as described with reference to procedure 500 in FIG. 6. In certain implementations, the EDA too 624 may be included as a feature of an existing compiler software program.

In certain implementations, an EDA (Electronic Design Automation) tool 624 can optimize droop detection in digital gates by integrating and enhancing the performance of a digital voltage sensor circuit. It achieves this through optimal placement of sensors near critical paths or high-load areas, minimizing interconnect delays, and dynamically calibrating sensor thresholds to account for process, voltage, and temperature (PVT) variations. The tool 624 partitions the design into segments with localized droop detection units to reduce latency and improve sensitivity. It also optimizes delay lines and thermometer-coded outputs within the sensor for high-resolution detection while balancing power and performance trade-offs. By simulating load scenarios, the EDA tool 624 identifies droop-prone regions, adjusts voltage thresholds (e.g., VT-types), and ensures seamless integration of feedback mechanisms to trigger compensatory actions, such as clock gating or voltage adjustments. Finally, system-level simulations ensure the droop detection circuit operates reliably under real-world conditions, enhancing the overall stability and performance of the digital system.

The procedure 400, for example, may be stored as program instructions as instructions 617 in the computer readable medium of the storage device 616 (or alternatively, in memory 614) that may be executed by the computer 610, or networked computers 620, 630, other networked electronic devices (not shown) or a combination thereof. In certain implementations, each of the computers 610, 620, 630 may be any type of computer, computer system, or other programmable electronic device. Further, each of the computers 610, 620, 630 may be implemented using one or more networked computers, e.g., in a cluster or other distributed computing system.

In certain implementations, the system 600 may be used with semiconductor integrated circuit (IC) designs that contain all standard cells, all blocks or a mixture of standard cells and blocks. In a particular example implementation, the system 600 may include in its database structures: a collection of cell libraries, one or more technology files, a plurality of cell library format files, a set of top design format files, one or more Open Artwork System Interchange Standard (OASIS/ OASIS.MASK) files, and/or at least one EDIF file. The database of the system 600 may be stored in one or more of memory 614 or storage devices 616 of computer 610 or in networked computers 620, 630.

In one implementation, the computer 600 includes a central processing unit (CPU) 612 (or graphics processing unit (GPU) 612, or neural processing unit (NPU) 6212 in certain implementations) having at least one hardware-based processor coupled to a memory 614. The memory 614 may represent random access memory (RAM) devices of main storage of the computer 610, supplemental levels of memory (e.g., cache memories, non-volatile or backup memories (e.g., programmable or flash memories)), read-only memories, or combinations thereof. In addition to the memory 614, the computer system 600 may include other memory located elsewhere in the computer 610, such as cache memory in the CPU 612, as well as any storage capacity used as a virtual memory (e.g., as stored on a storage device 616 or on another computer coupled to the computer 610).

The computer 610 may further be configured to communicate information externally. To interface with a user or operator (e.g., a circuit design engineer), the computer 610 may include a user interface (I/F) 618 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 610 may include a network interface (I/F) 615 which may be coupled to one or more networks 640 (e.g., a wireless network) to enable communication of information with other computers and electronic devices. The computer 560 may include analog and/or digital interfaces between the CPU 612 and each of the components 614, 615, 616, and 618. Further, other non-limiting hardware environments may be used within the context of example implementations.

The computer 610 may operate under the control of an operating system 626 and may execute or otherwise rely upon various computer software applications, components, programs, objects, modules, data structures, etc. (such as the programs associated with the procedure 400 and related software). The operating system 628 may be stored in the memory 614. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 626 in the example of FIG. 6 is shown in the memory 614, but components of the aforementioned software may also, or in addition, be stored at non-volatile memory (e.g., on storage device 616) and/or the non-volatile memory (not shown). Moreover, various applications, components, programs, objects, modules, etc. may also execute on one or more processors in another computer coupled to the computer 610 via the network 640 (e.g., in a distributed or client-server computing environment) where the processing to implement the functions of a computer program may be allocated to multiple computers 620, 630 over the network 640. In example implementations, circuit related diagrams have been provided in FIGS. 1-5, whose redundant description has not been duplicated in the related description of analogous circuit related diagrams. It is expressly incorporated that the same diagrams with identical symbols and/or reference numerals are included in each of embodiments based on its corresponding figure(s).

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user’s computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit comprising:
one or more delay line units, wherein each of the delay line units comprises: a first portion and one or more second portions, wherein:
the first portion comprises a NAND gate; and
each of the one or more second portions comprises a PMOS device and first, second, and third NMOS devices, and wherein:
each of the one or more delay line units is configured for an AND gate logic operation.

2. The circuit of claim 1, wherein for a respective delay line unit:
the first NMOS device is coupled between an output of the respective delay line unit and a reset input.

3. The circuit of claim 1, wherein for a respective delay line unit:
a gate input of the PMOS device is coupled to a gate input of the second NMOS device.

4. The circuit of claim 1, wherein for a respective delay line unit:
the second and the third NMOS devices are coupled in series.

5. The circuit of claim 1, wherein for a respective delay line unit:
first and second input signals are provided to the NAND gate; and
the first input signal is configured to activate the first NMOS device.

6. The circuit of claim 1, wherein for a respective delay line unit:
in response to activation of the first NMOS device, the first NMOS device is configured to provide conduction to an output of the respective delay line unit.

7. The circuit of claim 6, wherein:
in response to a deactivation of the second NMOS device, the PMOS device is configured to provide conduction of the output of the respective delay line unit.

8. The circuit of claim 1, wherein for a respective delay unit:
first and second input signals are provided to the NAND gate;
an inverse of the second input signal is configured to activate the third NMOS device; and
in response to an activation of the third NMOS device, the third NMOS device is configured to reset the respective delay line unit.

9. The circuit of claim 1, wherein for a respective delay line unit:
first and second input signals are provided to the NAND gate;
the first input signal corresponds to an output signal of a preceding delay line unit of the one or more delay line units;
the second input signal is a reset signal; and
an inverse of the second input signal is configured to concurrently reset the one or more delay line units.

10. The circuit of claim 1, wherein the first NMOS device is a same or lower VT-type device than the second and third NMOS devices.

11. The circuit of claim 1, wherein the circuit is comprised within a time-digital-conversion (TDC) circuit.

12. A method comprising:
receiving first and second input signals at a first portion of a delay line unit; and
activating a first NMOS device to provide conduction to an outputof the delay line unit, wherein:
at a second portion of the delay line unit, the first NMOS device is coupled between a reset input and the output; and
the first NMOS device is activated upon receiving the first input signal.

13. The method of claim 12, wherein the first portion comprises a NAND gate, and
further comprising:
in response to a transition of an output of the NAND gate, providing conduction to the outputthrough a PMOS deviceof the second portion.

14. The method of claim 13, wherein:
a gate of the PMOS device is coupled to a gate of a second NMOS device of the second portion, and
the second NMOS device is coupled to a third NMOS device in series.

15. The method of claim 14, further comprising:
activating the third NMOS device to reset the delay line unit, wherein:
the third NMOS device is activated upon receiving an inverse of the second input signal.

16. The method of claim 12, wherein:
the first input signal corresponds to an output signal of a preceding delay line unit of two or more delay line units; and
an inverse of a second input signal is configured to concurrently reset the two or more delay line units of a delay line.

17. A system comprising:
a clock generator circuit;
a pulse generator circuit; and
the circuit as claimed in claim 1, wherein the circuit is coupled to the clock generator circuit and the pulse generator circuit, and wherein the system is configured to predict a voltage droop of a processing unit.

18. A non-transitory computer-readable medium storing computer-readable code for fabrication of a circuit, comprising:
one or more delay line units, wherein each of the delay line units comprises: a first portion and one or more second portions, wherein:
the first portion comprises a NAND gate; and
each of the one or more second portions comprises a PMOS device and first, second, and third NMOS devices, and wherein:
each of the one or more delay line units is configured for an AND gate logic operation.

19. The non-transitory computer-readable medium of claim 18, wherein for a respective delay line unit:
the first NMOS device is coupled between an output of the respective delay line unit and a reset input.

20. The non-transitory computer-readable medium of claim 18, wherein for a respective delay line unit:
a gate input of the PMOS device is coupled to a gate input of the second NMOS device; and
the second and the third NMOS devices are coupled in series.
